(19) United States
(12) Patent Application Publication
(10) Pub. No.: US 2011/0114080 A1
(43) Pub. Date: May 19, 2011

(54) Multi-Axis Metamorphic Actuator and Drive System and Method

(76) Inventors: Peter Childers, Palo Alto, CA (US); Jonathan N. Blitz, Durham, NC (US)

(21) Appl. No.: 12/919,795

(22) PCT Filed: May 23, 2008
(86) PCT No.: PCT/US08/06660

§ 371 Date: Jan. 14, 2011

Related U.S. Application Data
(60) Provisional application No. 61/064,351, filed on Feb. 29, 2008.

(51) Int. Cl. F24J 2/40; B66F 3/24; B66F 3/46; F24J 2/38; H01L 31/042

(52) U.S. Cl. 126/601; 254/93 R; 126/584; 126/604; 136/244

(57) ABSTRACT

An embodiment of a system and method for moving an object in two or more axes includes one or more fluid containers, each of which is directly or indirectly in physical contact with the object. A volume of a fluid is placed in the one or more fluid containers. The system further includes a fluid mover operably connected to the one or more fluid containers for moving the fluid into the one or more containers, and a fluid volume control for controlling the volume of fluid in the one or more containers. By changing the volume of fluid in the one or more containers, the containers are variably pressurized, thereby moving the object in one or more axis. The object may be supported at one or more pivot points that allow the object to be moved in multiple axes.

### TECHNICAL FIELD

The technical field relates to systems and methods for supporting and moving an object in two or more axes. The system for supporting and moving an object in two or more axes can be applied to any of a wide variety of fields as a complete replacement for older technologies, mechanisms, and methods for moving, driving, positioning, or actuating objects or loads or tools in precise or non-precise multi-axis orientation, such as for the positioning of heliostats, solar tracking systems, electromagnetic radiation antennas, and other large or small objects.

### DESCRIPTION OF RELATED ART

Actuators of various kinds are currently used to manipulate and position objects in multiple axes of orientation, altitude, and azimuth in various fields such as solar power, astronomy, satellite, radar, thermal imaging, construction, and advertising. With respect to large scale or heavy equipment applications, current actuators employ gear drives, planetary gears, worm drives, rack and pinion, hydraulic pistons, pneumatic pistons, screw drives, and various clockwork machinery to position large and heavy objects around stationary mounts. Due to their reliance on electrical motors to move heavy and large objects, current actuators require large numbers of precision-engineered parts and significant electrical power supply. These means use expensive hoses and cabling to transmit power. In addition, current multi-axis actuators also use multiple heavy connections between structural members and actuators to support and position heavy and large objects. Although simplified actuators are available, they do not have the capability to position heavy and large objects in multiple axes. For example, U.S. Pat. No. 4,560,145 discloses an airbag jack that can lift or move an object in one axis using a single airbag to force the object to move.

Another disadvantage of current multi-axis actuators is that due to their heavy weight and precision metal-to-metal gearing and mechanics, normal metal fatigue, operational wear-and-tear and external stresses such as dust, contaminants, foreign objects, lubrication problems, and even minor operator errors and omissions create significant use-related damage, chattering, freeplay, and consequent degradation in accuracy and durability. Such actuators, which are also known as “clockwork” actuators, necessitate high costs of inspection, maintenance, repair, and replacement of precision-machined components, and consequent downtime from productive operations. The clockwork actuators do not provide a smooth tracking motion, but a periodic stepping motion common to electric motorized systems.

Clockwork actuators can be used in connection with solar energy collection devices that rotate in multiple axes to maintain the desired orientation of a panel of solar cells and solar thermal collectors or mirrors throughout the day and year. These devices are referred to as “heliostats” or “positioning systems.” Thus far, current positioning systems are complex and expensive. Particularly as the size of the of the mirrors and photovoltaic panels increase to over 100 m² on a single tracker, the complex precision gear drives and powerful motors required to maneuver and stabilize the panels, particularly in high wind conditions, have emerged as the largest single cost barrier in pursuing large scale solar power generation. These clockwork actuators are delicate and prone to mechanical failure or degradation under normal and abnormal operating conditions. These and other limitations of current heliostat technology are among the chief barriers to lowering the cost of electrical generation via solar thermal or concentrated solar energy to equal or below cost of electricity from coal and natural gas-fired generating plants.

Other typical examples of the current heliostat technology include U.S. Pat. No. 3,070,643 disclosing a closed loop servo system for continuously pointing a solar cell directly toward the sun by sensing the sun's position using a complicated gearing system with a single drive motor and an electrically operated clutch to permit selective dual-axis drive. Another system, disclosed in U.S. Pat. Nos. 3,998,206 and 3,996,917, employs separate drive motors for obtaining dual-axis movement. The use of motor drives and gear reduction adds significantly to the cost of initial installation and maintenance of a sun tracking apparatus. In addition, the power required to drive the powerful motors creates a parasitic power drain on the operation of the solar power plant. The use of gear and motor drives is typical of the current actuators as disclosed in, by way of example, U.S. Pat. No. 6,440,019.

Another disadvantage of the current heliostat technology is its reliance, in most cases, on external sources of power. The current actuators require the provision of electrical or hydraulic power to orient the application, which generates a parasitic power drain on the installation, and also requires complicated and expensive electrical or hydraulic power distribution systems using cables or hoses for their operation. By their nature, heliostat arrays often cover many square kilometers, and thus, over a large installation, the provision of external power through cables to an array of thousands of heliostats adds to major capital and maintenance expense. The current actuators fail to achieve a low cost means of providing multi-axis sun tracking with minimal power requirements.

Another disadvantage of current heliostats relying on clockwork gear drives is that the gear drive system for actuation also serves as the multi-axis hinge or bearing and thus can exert its forces at a single point and over a very small area. Therefore, the clockwork gear drives apply forces for directional control with very weak leverage.

Furthermore, clockwork gear drives are not suited to operate under uneven loads or shearing forces. The momentum created by a heliostat system, for example, will create a shearing force on the gear drive. Any shearing forces or uneven loads applied to the edges or sides of the application structure, for example by winds or other externalities, create dynamic loads with a very long moment arm. The shearing forces exert massive torque forces upon the gear drive, making it difficult to operate.

A further disadvantage of current actuator systems is the high cost of maintenance. Maintaining or replacing components of a gear drive usually requires the dismasting and removal of an entire application surface, since the gear drive serves as the hinge or fulcrum bearing and single point of attachment for the application to the mast. Accordingly, there is a need for an improved, cost and power efficient multi-axis actuator for use in small to large scale applications.

### SUMMARY

An embodiment of a system for moving an object in two or more axes includes a fluid and three or more fluid containers. Each of the three or more fluid containers is directly or indirectly in contact with the object. A volume of the fluid is placed in at least one of the three or more fluid containers. The system further includes a fluid mover operably connected to the three or more fluid containers for moving the fluid into the three or more containers. The system further includes a fluid volume control for controlling the volume of fluid in the three or more containers. The object may be supported at one or more pivot points. By changing the volume of fluid in the three or more containers, the object is moved.

An embodiment of a system for moving an object in one axis includes two or more fluid containers, each of which is directly or indirectly in physical contact with the object. A volume of a fluid is placed in the two or more fluid containers. The system further includes a fluid mover connected to the one or more fluid containers for moving the fluid into the one or more containers, and a fluid volume control for controlling the volume of fluid in the one or more containers. By changing the volume of fluid in the two or more containers, the object is moved.

A method for moving an object in two or more dimensions using pressurized fluid includes providing a pivot point, applying pressure on or in support of the object on at least three or more locations using pressurized fluid, and changing the pressure applied at a location by changing the volume of the pressurized fluid. The change in pressure moves the object.

A method for moving an object in two or more dimensions using pressurized fluid includes providing fluid containers, providing a pivot point, providing a guidance system that sends a need for a change in position, providing a control system that receives a data signal from the guidance system, interprets the data signal, and converts the data signal into pressure changes or fluid volume changes. The control system activates one or more pumps or compressors to change the volume of the pressurized fluid in one or more of the fluid containers. The change in volume of the pressurized fluid moves the object.

### BRIEF DESCRIPTION OF THE DRAWINGS

FIG. 1 shows a side view of an embodiment of an exemplary system for moving an object in two or more axes for a large heliostat;

FIG. 2 shows a cross sectional top view of an embodiment of a system for moving an object in two or more axes;

FIG. 3 shows an isometric side view of an embodiment of the exemplary system of FIG. 2 with details of the fluid containers in a state of differential inflation, configured as an annular ring;

FIG. 4 shows a side view of a system for moving an object in two or more axes with a recessed fulcrum;

FIG. 5 shows a side view of an embodiment of the system for moving an object in two or more axes as a two-dimension actuator, with two fluid containers;

FIG. 6 shows a side view of a system for moving an object in two or more axes with inflatable fluid containers in a compressed position;

FIG. 7 shows a side view of a system for moving an object in two or more axes with fully inflated fluid containers;

FIG. 8 shows a side view of a system for moving an object in two or more axes including multiple embodiments of the system working as one system;

FIG. 9 shows a side view of a system for moving an object in two or more axes with an inverted upper support structure.

FIGS. 10a and 10b represent schematic diagrams of a manifold of air or fluid tubes for pressurizing and de-pressurizing each fluid container;

FIG. 11 shows a schematic diagram of the control system of a system for moving an object in two or more axes;

FIG. 12 shows a schematic diagram of the on-board power supply of a system for moving an object in two or more axes;

FIG. 13a shows a perspective view of a system for moving an object in two or more axes deployed for tracking a telecommunications satellite receiver antenna;

FIG. 13b shows a perspective view of a system for moving an object in two or more axes used on a space vehicle or space station in applications requiring robotic arms or actuators;

FIG. 13c shows a perspective view of a system for moving an object in two or more axes for rotation of antennae in alignment with receivers;

FIG. 13d shows a perspective view of a system for moving an object in two or more axes deployed as a heliostat on a planet in outer space;

FIG. 14a shows a perspective view of the system for moving an object in two or more axes embodied as a greenhouse illuminator;

FIG. 14b shows a perspective view of a system for moving an object in two or more axes embodied as an illumination or heating system for residential or commercial buildings, or for illuminating otherwise shaded public spaces;

FIG. 15a shows a perspective view of a system for moving an object in two or more axes embodied as medical robotics actuator;

FIG. 15b shows a perspective view of a system for moving an object in two or more axes embodied as a prosthesis for a missing limb;

FIG. 15c shows a perspective view of a system for moving an object in two or more axes embodied as a micro surgical manipulator for endovascular surgery or micro surgery via laparoscope;

FIG. 15d shows a perspective view of a system for moving an object in two or more axes employed to position a radiation source used for medical treatment; and

FIG. 16 is a flow-chart showing a method for moving an object in two or more axes.

Before one or more embodiments of the system for moving an object in two or more axes are described in detail, one skilled in the art will appreciate that the system for moving an object in two or more axes is not limited in its application to the details of construction, the arrangements of components, and the arrangement of steps set forth in the following detailed description or illustrated in the drawings. The system for moving an object in two or more axes is capable of other embodiments and of being practiced or being carried out in various ways. Also, it is to be understood that the phraseology and terminology used herein is for the purpose of description and should not be regarded as limiting.

### DETAILED DESCRIPTION

The system for moving an object in two or more axes is a new type of multi-axis actuator drive mechanism and system that can be embodied in a wide variety of uses or applications requiring multi-axis control and orientation of objects of various size and weight. The device is particularly suited to multi-axis control and manipulation of large and heavy objects under external stresses including sustained and gusting winds, and shifting loads. The system can be employed for various applications including infrared optical sensors, advertising materials, hoists and cranes, machines and equipment for maintenance and repair, and for the manipulation of remote tools or surgical implements, among many applications at large scale to small scale.

Actuators can be used in the collection of solar energy. Solar energy can be collected through the concentration of sunlight by aiming an array of mirrors such that they reflect sunlight into a single fixed receiver to produce concentrated heat for steam production. For an example of such a power plant see U.S. Pat. No. 6,957,536. The motion of the earth in rotation and around the sun in orbit necessitates a mechanism for aligning the mirrors or panels in a position relative to the sun as it moves across the sky on a daily basis and relative to the horizon on a seasonal basis so that solar energy is continuously reflected onto the receiver. In practical terms, devices to constantly orient a collector or minor toward the sun must provide a means for continuously adjusting azimuth (rotation around the horizon line) and altitude (rotation from the horizon to a position directly overhead) to continuously track the apparent motion of the sun through the sky.

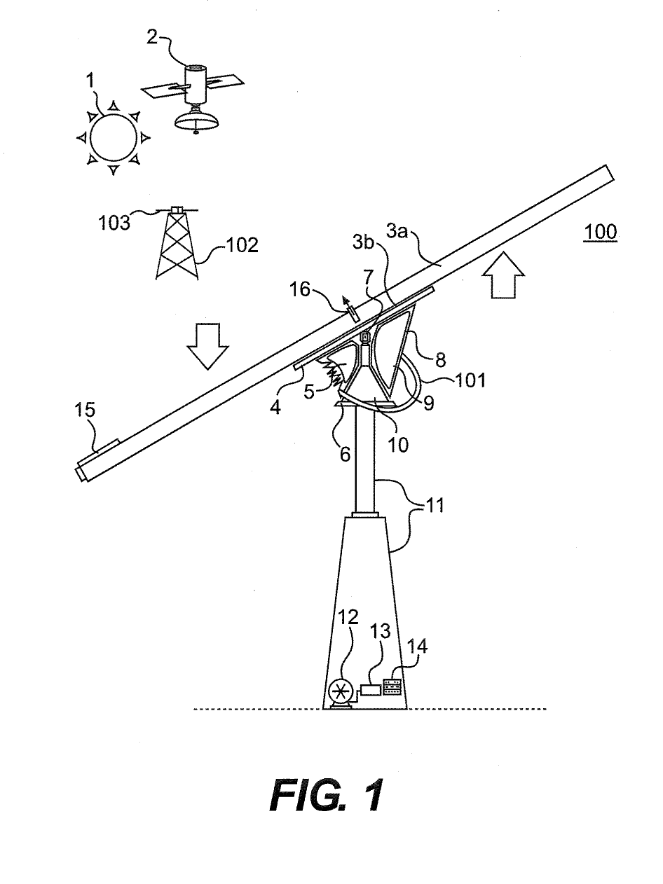

An embodiment of the system for moving an object in two or more axes is illustrated in FIG. 1. The exemplary embodiment includes tracking related to solar-energy and solar reflection. The system can be used to position photovoltaic panels, solar reflecting mirrors and other similar components of solar power plants or solar power-related systems on large or small scale, for industrial, agricultural or residential use, for tracking the movement of the sun or reflect the sun continuously at a target, as is required by numerous solar energy-related applications. The exemplary system for moving an object in two or more axes makes possible a heliostat application of a size that is greater than a thousand square meters.

Referring now to FIG. 1, a side view of an embodiment of a system for moving an object or application in two or more axes 100 is shown in relation to example targets such as the sun 1 and a solar receiver tower 102. The exemplary embodiment includes the object, or application 3a to be manipulated or positioned. The object 3a may include a large solar reflecting or collecting surface such as a mirror or photovoltaic panel, for example, and may be mounted on an application support structure 3b which can include a mounting rack that is mounted upon an upper support structure 4. In some embodiments, the application support structure forms an integral part of the upper support structure 3b. The upper support structure 4 includes a rigid, fixed surface that is anchored or joined via a universal, multi-axis joint such as a gimbal joint 7, to the central support structure 11. The bottom side of the upper support structure 4 serves as a solid surface against which the fluid containers exert upforce and lateral force to move and drive the exemplary application in a desired direction or alignment. The top side of the upper support structure 4 may serve as the attachment point for various applications and may integrate with, adapt to, or function as part of the exemplary application, and vice-versa.

Furthermore, the system for moving an object in two or more axes may also include a central support structure 11 comprising metal and/or concrete located beneath the upper support structure 4 and a universal joint 7. The universal joint 7 may include a carden joint, one or more gimbals, or any other multi-axis coupling or bearing capable of a range of motion in multiple axes, strength and durability for coupling the upper support structure 4 with the central support structure 11 such that the upper support structure 4 can freely pivot upon the top of the central support structure 11.

With continued reference to FIG. 1, the exemplary embodiment of system for moving an object in two or more axes further includes a group of at least three fluid containers, also referred to as fluid inflatable containers 9, that each may include a flexible sealed bag or membrane of one or more compartments, attached around the central support 11, between the upper support structure 4 and the lower support structure 10. The lower support structure can be comprised of various shapes, in this figure it is cone-shaped. In addition, the ground can be the lower support structure 10 The fluid inflatable containers 9 act as actuators that exert forces upon other elements of the system for moving an object in two or more axes to cause mechanical movement, control, and alignment as desired. The fluid inflatable containers 9 may be inflated with varying amounts of non-volatile gas or fluid to assume rigid or semi-rigid forms of varying shape and size differentially depending on the degree of inflation or filling required for moving an object 3a to a desired position. In an embodiment, the fluid can be air, water, gas, oil, high density fluid, high viscosity fluid, and/or a solid at ambient temperature. For example, when the object or application needs to be moved, the solid fluid may be heated by a heating device, such as electrical heat strips, and transformed to a liquid. The electrical heat strips can be located inside or outside of the fluid inflatable containers in direct or indirect contact with the containers and/or the solid fluid. After the object or application is in place, the liquid may be cooled to ambient temperature and transformed back to a solid by reducing the heat emitted from the heat strips. An example of a fluid that can be used in an embodiment is a paraffin wax with a melting point between 125 to 165 degrees fahrenheit. Furthermore, the fluid may be comprised of an electrical field-sensitive gel that would increase in viscosity to reach a solid state.

In an embodiment, three or more fluid inflatable containers 9 may be located at the top, bottom, side, or corners of the object or application. An embodiment with six fluid inflatable containers 9 is shown in FIG. 3 at the bottom of the object 3a. In another embodiment, one or more fluid inflatable containers 9 is located at one or more locations (top, bottom, side, and corners) in direct or indirect physical contact with the object to be moved. In another embodiment, all of the fluid inflatable containers 9 may be located on the top of the object. Alternatively, some of the fluid inflatable containers 9 are located on the top of the object while some are at the bottom. The system may include a connection between any two of the fluid inflatable containers 9 for passing fluid. Fluid containers at the top and bottom of an object but on opposite sides of a pivot point may be connected with a tube to pass fluid 101. Additionally, fluid containers that are located on the same side of the object can include a tube to pass fluid 101. Furthermore, elastic tensioning devices (not shown) can be used along with the three or more fluid containers 9 or to replace one or more fluid containers, to support or move an object. The elastic tensioning device can include a spring.

Furthermore, the fluid containers 9 may be in contact with one another. The fluid containers may be attached to one another by various means including a direct or indirect attachment or connection, or the containers may be attached or secured independently. An optional sleeve, sheath or shroud 8 for each fluid container 9 may be positioned to encapsulate part or all of a fluid inflatable container serving to protect, contain and shape the container or a group of containers, performing like a corset. The sleeve 8 also serves as a surface on which to attach connectors 35 (shown in FIG. 7) for connecting the fluid containers to one another circumferentially around the central support 11, to anchor points on the upper 4 and lower 10 support structures, as needed and to connect with other parts of the system for moving an object in two or more axes.

The system for moving an object in two or more axes further includes a lower support structure 10 fixed circumferentially to the central support. In some embodiments, the ground or another object or application may serve as a lower support structure 10. The lower support structure 10 includes a fixed surface below the fluid inflatable containers 9 that acts as a solid surface against which the containers 9 exert downforce. The system for moving an object in two or more axes also stabilizes large heavy objects in a variety of wind conditions by using a balance of forces produced by the strategic placement and pressurization of fluid inflatable containers 9 and the static force of the lower support structure 10.

The system for moving an object in two or more axes further includes a rim stop 6 or other shock absorbing surface or device on or around the perimeter of the lower support structure 10, a fluid delivery system that includes a manifold of air or fluid tubes 13 connected to control valves 42 for pressurizing and de-pressurizing each fluid container, a source of compressed air or other fluid 12, and a control unit 14 including power supplies and controls for the compression system and fluid delivery system. The manifold 13 may include one or more tubes inside of the larger manifold. Additionally, the system for moving an object in two or more axes can include an onboard power supply system 15.

The control unit 14 of the system for moving an object in two or more axes also may include a positioning system that can include both wired and wireless control systems that are remotely controlled without requiring external control cabling.

The exemplary system for moving an object in two or more axes may be embodied to include a laser positioning system as either a primary or secondary guidance system or positioning feedback system whose components can include a laser beam emitter 16 that is fitted onto the upper support structure 4 or the object or application 3a. The laser beam emitter 16 emits a laser beam from the object or application surface at a known angle relative to the application support structure 3b. The laser beam is detected by a laser sensor 103 at the top of a solar receiver 102 tower or other target. The control unit 14 can orient the upper support structure and object or application in the most advantageous position for insolating the receiver 102 by processing information from the laser sensor 16 communicated electronically from the sensor to the computer.

Moreover, the system for moving an object in two or more axes provides highly dispersed but precisely controlled mechanical force to cause movement and precision positioning through the differential systematic pressurization and depressurization of the fluid containers configured in a variable-shape formation to be known as a metamorphic cam, metamorphic collar, metamorphic drive, or metamorphic actuator. The fluid containers 9 provide the driving force and torque required for multi-axis positioning while the universal joint 7 provides mechanical downforce, support, and rotation from a single fixed point or bearing. Instead of relying on the same device to perform precision actuation and axial pivoting or bearing, which must engage in and continuously apply physical lifting, directional control, and support from a single point, the pivoting and load-bearing functions of the system for moving an object in two or more axes are primarily borne by and concentrated in an universal joint, carden joint, bearing, or other such pivoting support structure 7. Such joint need not be a precision component and is relieved of having to actuate the positioning or exert driving force, leverage, or torque. Instead the joint serves its role in weight-bearing and acts as a fulcrum or hinge for torque applied by the fluid containers. The fluid containers 9 may be configured as a metamorphic cam and perform the function of a metamorphic cam. The metamorphic cam formed by the fluid containers 9 enables the whole system to perform as a type of drive and multi-axis actuator system and method for moving an object in two or more axes. The multi-axis actuator component of the system for moving an object in two or more axes thereby performs the main work of guidance, control, direction, positioning, and as such acts independently and supplementary to the primary weight-bearing and pivoting structure of the universal joint 7.

The system for moving an object in two or more axes accomplishes precision actuation and positioning of objects of large or small size mass. The exemplary system accomplishes this while easily absorbing and dissipating vibration and impact that are evenly or unevenly applied to objects by externalities under normal and abnormal conditions. The fluid inflatable containers 9 configured as a metamorphic cam, exert and absorb forces over a much larger surface area and thereby shorten the moment arm of torque and distribution of torque or loads applied to the object 3a and upper support structure 4.

The fluid inflatable containers 9 require modest pressure in order to move an application 3a, depending among other factors on the number of fluid containers, the material, strength, size, and contact area of the fluid containers, and configuration of sleeves 8. The exemplary pressure range is estimated at from 0.4 pounds per square inch to 10 psi, which is comparable pressure for example, to pressure at which natural gas is supplied to households by public service gas companies or in common household and recreational inflatables such as basketballs, camping mattresses and inflatable boats. Use of a much wider range of pressure is possible (e.g. 0.1 to 100 psi). The force of pressure inside the fluid containers 9 is magnified by the surface area over which the actuators apply force to move the object or application, and this distributed force allows them to easily absorb inertia or momentum created by the object or application 3a itself or exerted by externalities acting upon the object or application.

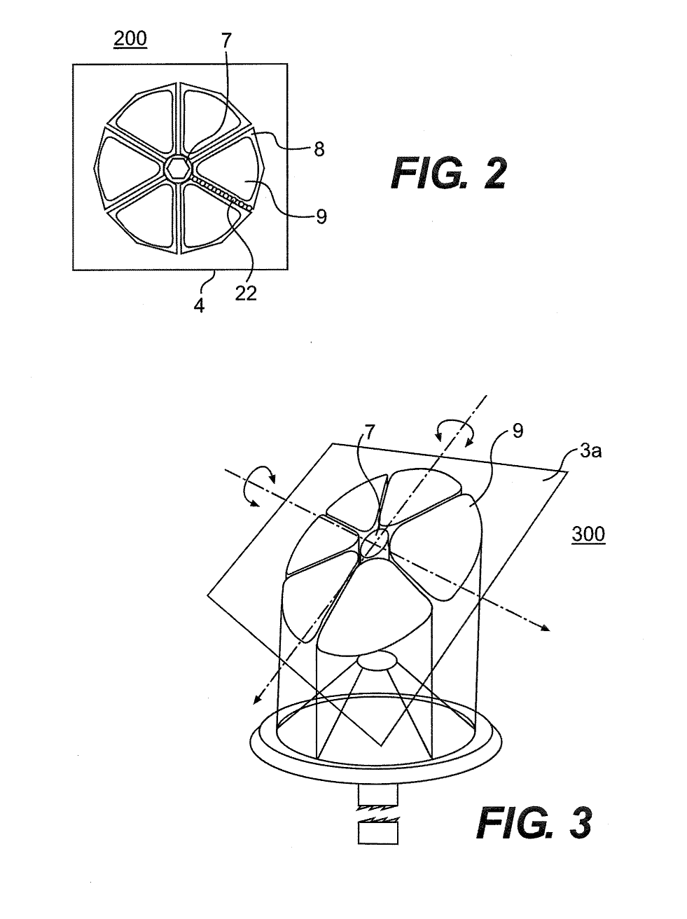

Referring now to FIG. 2, shown is a cross sectional top view of an embodiment of a system for moving an object in two or more axes 200 including at least three or more fluid inflatable containers 9. In this exemplary embodiment, shown are six fluid inflatable containers 9 connected by linkages 22 in an annular ring configuration. Several elements of the embodiments may vary significantly while not changing the essential function or mechanism of action of the system for moving an object in two or more axes. In one embodiment, one or more spring-loaded tensioning cables or other elastic tensioning devices may be substituted for one or more fluid inflatable containers, or may be used in conjunction with the fluid inflatable containers 9 to stabilize the object or application and/or the upper support structure during installation, maintenance, replacement. The embodiment may include the use of stacked, nested, folding, accordion, or inter-leafing or leaf-shaped or configured fluid inflatable containers 9. Springs may be added inside the fluid containers or containers.

The fluid inflatable containers 9 are arranged inside of sleeves 8 by linkages or other connection types. The sleeves contain and channel the force generated by inflation of the fluid inflatable containers 9. When pressurized with fluid, the fluid inflatable containers seek to assume a longer, straighter configuration in accordance with their fully-inflated design, expanding with tremendous uniformly dispersed mechanical force equal to the surface area of the container multiplied by the pressure introduced. The sleeves 8 may include any continuous or discontinuous sheathing material of widely varying flexibility, strength, puncture and weather-resistance. The sleeves 8 may be made of one or more of man-made material, natural material, rubber, vinyl, canvas, ballistic nylon, steel mesh, cotton webbing, or other woven or manufactured natural or man-made fabric or textile or sheet product. The sleeves 8 may include any of a variety of fabric or non-fabric sheet(s), netting, straps or connectors attached to or around the containers themselves, or be integrated as part of the containers.

Additionally, a sleeve 8 may be comprised of metal in a collapsible or telescopic form. A sleeve 8 may be made of similar material as the containers 9, or a semi-rigid fabric or a solid or rigid solid surface molded or affixed to the upper support structure 4 and/or lower support structure 10. An embodiment of the system for moving an object in two or more axes may include various methods of connecting sleeves 8, which may include providing attachment points for connectors to connect sleeves 8 together. Another method of connecting sleeves is using pure friction without employing fixed attachment points.

FIG. 3 shows an isometric view of a line diagram 300 showing the degrees of freedom in which the upper support structure 4 of a system for moving an object in two or more axes can move as the fluid inflatable containers are differentially deflated and inflated.

An alternative embodiment may include the use of one or more multi-chambered containers 9 (arranged in any of multiple shapes or configurations) for incrementally controlled inflation and deflation, and/or for control of buckling or deformation. The specific shape of the fluid inflatable container 9 may vary widely, and may change during operation, such that they resemble shapes including wedges, cones, cylinders, pontoons, arcs, crescents, or globes. In the embodiment shown in FIG. 3, the fluid inflatable containers 9 resemble wedges.

Referring now to FIG. 4, a side view 400 is shown of the system for moving an object in two or more axes in which the upper support structure 4 is configured with a recessed fulcrum, wherein the universal joint 7 is the pivot point. The embodiment may be constructed so that the object 3a may be self-balancing under neutral stress by means of the recessed-fulcrum configuration of the upper support structure 4. In this embodiment, the upper support structure 4, is above the center of gravity, thereby suspending the object 3a, which can balanced in a neutral position as level with the ground.

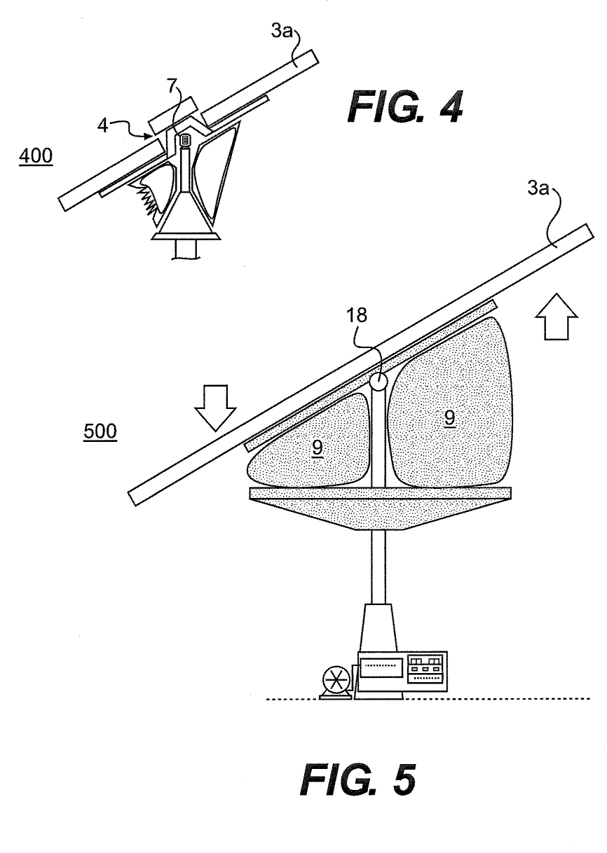

Referring now to FIG. 5, a side view 500 is shown of an embodiment of the system for moving an object in two or more axes that comprises a simplified actuator system for moving an object in two dimensions. The simplified actuator system is shown with two inflatable fluid containers 9 that can move the object 3a on a simple hinge or bearing on a single axis of rotation 18.

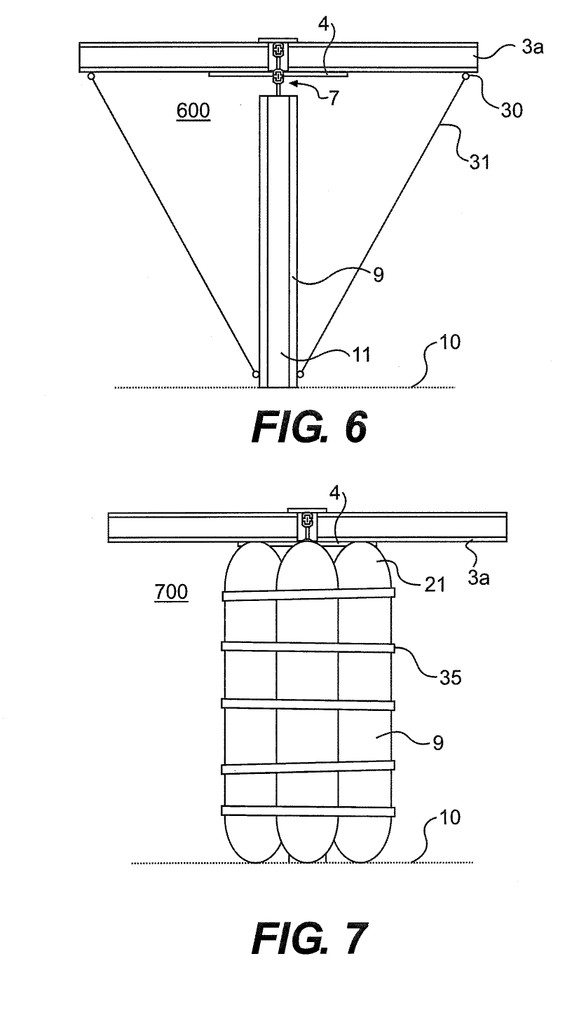

Referring to FIG. 6, a side view 600 is shown of an embodiment of the system for moving an object in two or more axes when first installed, in which the fluid inflatable containers 9 are fully deflated and assume a compressed position. The support structure 4 can be locked in a neutral or stowed position during installation, maintenance or disassembly if tensioning cables 31 are attached and tensioned between corresponding cable anchor points 30. Accordingly, this allows the entire system to be stabilized independently of the fluid inflatable containers 9 and the support structure 4 to be stowed in a secure configuration such as may be required at time of installation, and during periods of maintenance work such as the deflation and repair or replacement of the fluid inflatable containers or other components of the application. When the system is in the “stowed” position, the application 3a and upper support structure 4 are supported by the central support structure 11 and the universal joint 7. The upper support structure may be tilted completely to one side, or may be stabilized by tensioning cables 31.

As fluid pressure builds within each fluid inflatable container, the fluid inflatable container seeks to balance the building fluid pressure by straightening. The relative expansion of each fluid inflatable container simultaneously exerts lateral expansive and constrictive force around the central support 11 and with respect to one another and the sleeves or shrouds, creating strong downforce pressure against the lower support structure and thereby actuating the upper support 4 with upforce against the area of the upper support structure directly above the fluid inflatable containers. The upward forces propel and drive the upper support 4 (and thus the application sought to be positioned) across multiple axes of rotational movement anchored at the center by the universal joint 7. The upper support structure 4 is fixed in a desired position by balancing the pressures exerted by the fluid inflatable containers upward and with respect to each other against the downward pressure of the universal joint 7 and the upward pressure of the lower support structure 10, shown here representing the ground. Movement of the upper support structure to any position within a 360° field of azimuth and a 180° altitude can be accomplished by systematically pressurizing and de-pressurizing the fluid inflatable containers by use of the pressure control valve(s) operatively connected to each fluid inflatable container. When changing position, the container or containers positioned opposite the direction of movement are depressurized to allow the pressure of the container or containers opposite the direction of movement to force the surface into the desired position. Once the upper support structure is in the desired position, all of the containers will be pressurized to exert equal pressure and hold the application rigidly in position. The speed of the desired movement is controlled by the speed of the pressure changes.

Referring to FIG. 7, a side view 700 is shown of an embodiment of the system for moving an object in two or more axes pressurizing all of the fluid inflatable containers 9 in the illustrated embodiment to equilibrium of pressure and volume will orient the object 3a in a horizontal level position. The surfaces of fluid inflatable containers that come into contact with the upper and lower support structures can be comprised of various shapes. Here, the fluid inflatable bladders are shown with arcuately-shaped contact surfaces 21. The system can move an object or application in a stop-and-go fashion or in a continuous, smooth motion without a stepping function. Sudden stops and changes in momentum of even heavy applications are easily borne by the system for moving an object in two or more axes without damage, since the mechanism naturally disperses and absorbs shocks as elastic rather than inelastic impacts or collisions.

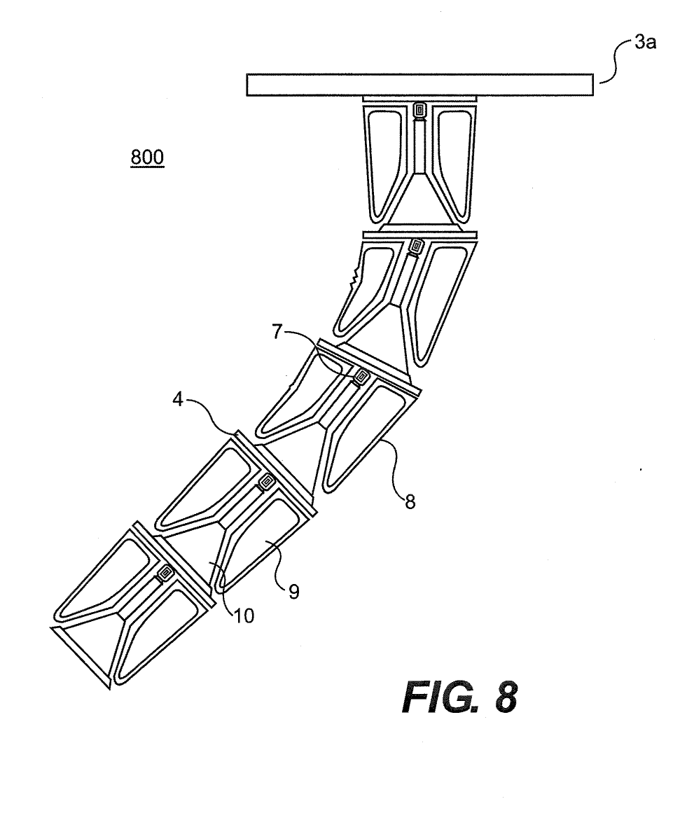

Referring now to FIG. 8, a side view 800 the system for moving an object in two or more axes wherein multiple actuators are attached together and work as one unit to move the object 3a. This embodiment fulfills a need for certain applications that may require multiple metamorphic actuators to be connected in sequence. In this embodiment, the upper support structure 4 of one actuator assembly attaches indirectly or directly to the lower support structure 10 of another actuator assembly or assemblies to enable a greater degree of mobility for a tool or application to negotiate multiple multi-axis twists and turns, including endovascular applications or in mining or search and rescue, for example.

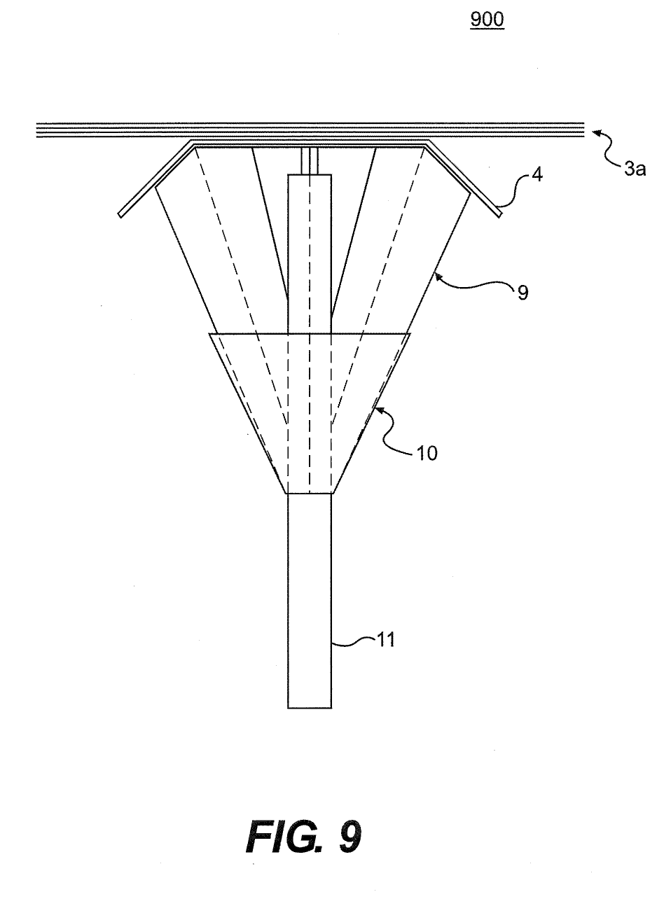

Referring now to FIG. 9, shown is a side view of an embodiment of a system for moving an object in two or more axes with an inverted upper support structure 4 and inverted lower support structure 10 to provide simultaneous support and containment to the fluid inflatable containers 9. More particularly, the lower support structure 10 forms an inverted, hollow, partial cone or sleeve into which the fluid inflatable containers are placed. The upper support structure 4 is shaped into an inverted bowl or upright, hollow, partial cone into which the fluid inflatable containers expand. This embodiment uses the upper and lower support structures for simultaneous support and containment eliminating the need for a separate fabric constraint on the fluid inflatable containers. In addition, this embodiment provides the added benefit of reducing the complexity and weight of both the upper and lower support structures. Moreover, this embodiment allows greater accuracy in positioning the application 3a, by reducing the non-linear responses to pressure and volume changes caused by the fabric constraint of the fluid inflatable bladders 9.

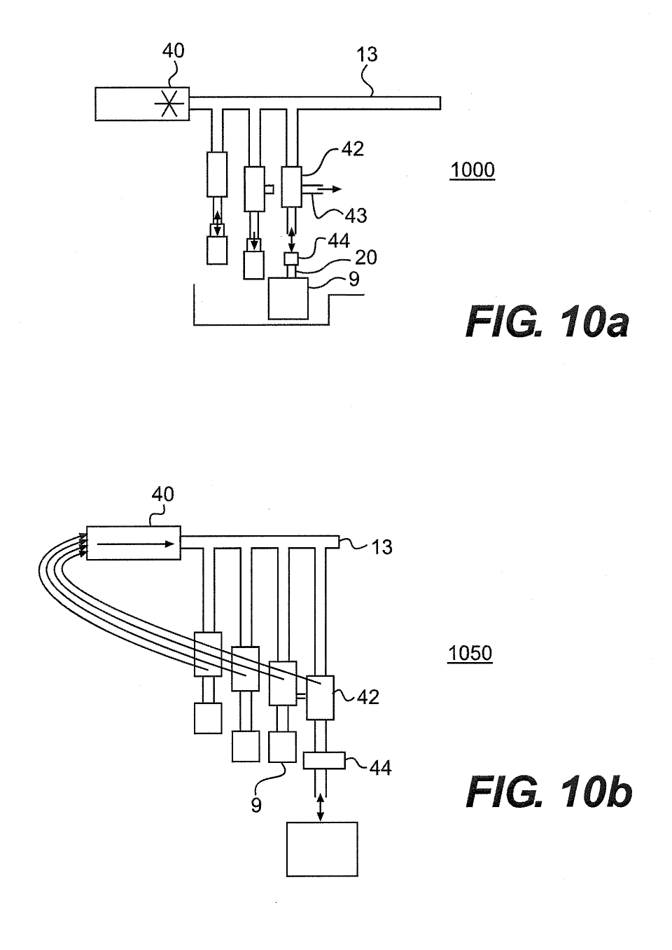

Referring now to FIG. 10a, a schematic view 1000 of the valve manifold 13, in an embodiment of a system for moving an object in two or more axes is shown. The valve manifold 13 will usually have a pressure transducer port for connecting pressure transducers 44 to the fluid inflatable containers 9, an exhaust solenoid valve port 43 and an inflation solenoid valve port 45. A inflatable container 9 may include an inflation source, generally comprising a hose 20 and a compressor 40 for pressurizing and de-pressurizing each fluid container 9. container or sealed sub-chamber therein will include an inflation source, generally comprising a hose 20 and a compressor 40 for pressurizing and de-pressurizing each fluid container 9. The fluid containers 9 may be de-pressurized by other means besides a compressor, such as a release valve for air, for example. A single three port valve 42 could provide inflation and deflation using some of the valves, or one valve per container. Some embodiments of the system for moving an object in two or move axes may allow excess air upon deflation too bleed into the atmosphere, such as when the system is employed on the ground in normal conditions. Other embodiments of the system may allow air to bleed from one container into another or into a holding tank because applications in the upper atmosphere, space, and underwater applications may need to reuse all available air in a closed system, shown in FIG. 10b.

Referring now to FIG. 10b, a schematic view 1050 of the valve manifold 13, in an embodiment of a system for moving an object in two or more axes is shown connected to three-way control valves 42 that may be variably controlled via computer and a compressor 40 for pressurizing and de-pressurizing each fluid container. The manifold in this exemplary embodiment also includes pressure transducers 44 shown connected to fluid inflatable containers 9. The exhaust is shown re-circulating to an inlet in the compressor 40.

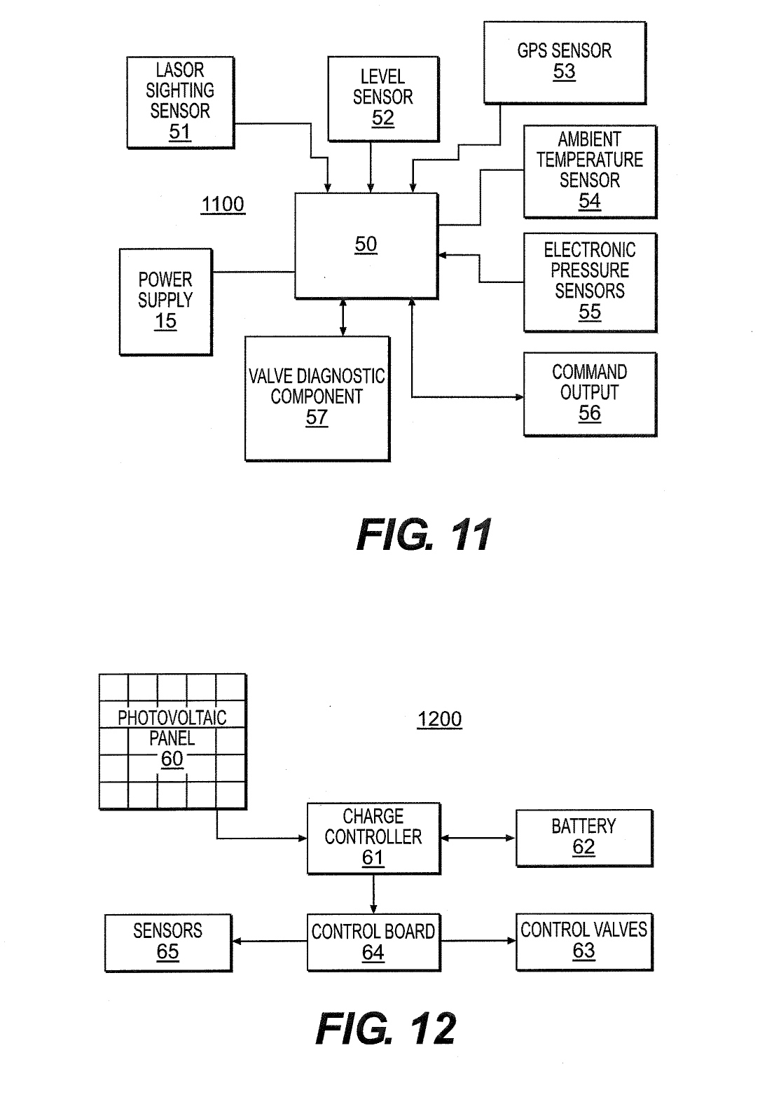

FIG. 11 shows a block diagram 1100 of a self-contained positioning power control unit 14 of the system for moving an object in two or more axes that is shown located at the base of the central support structure 11 in FIG. 1 of this exemplary embodiment. The control unit 14 may comprise a guidance system including sensors such as laser sighting sensors 51, electronic level sensors 52, GPS sensors 53, ambient temperature sensors 54, a control computer including computer hardware and software 50 for directing the fluid inflatable containers 9 in moving an application 3a. The computer 50, directs each fluid inflatable container 9 to move the upper support structure 4 and hence the object or application 3a to the desired position to maintain optimal orientation with respect to the target by processing information from the electronic pressure sensors 55 (that can be connected to each of the fluid inflatable containers on any part of the fluid inflatable containers), the ambient temperature sensors 54, and the electronic level sensors 52 (for detecting altitude and azimuth).

In addition, the computer 50 can calculate the present position of the application 3a or upper support structure 4, determine the air volume and pressure changes necessary to move the application 3a, and activate the valves and manifold system to pump compressed air into those fluid inflatable containers 9 that need to inflate and simultaneous release air from those that need to deflate in order to actuate or drive or otherwise move the object or application 3a to the desired position. The computer effects inflation and deflation of the fluid inflatable containers 9 by electronically actuating the compressor 40 and control valves 42 while simultaneously comparing and correcting the motion of the support structure 4 by evaluating the feedback obtained from the electronic level sensors 52.

The control unit further comprises an onboard power supply 15, a compressor and valve control diagnostic component 57 for sending and receiving signals to the control computer 50. The control computer 50 receives signals from the sensors to determine commands for directing the actuators 9. The control computer 50 outputs movement commands 56 to a remote control system using a current telecommunications standard including WiFi and/or WiMax.

Referring now to FIG. 12, a block diagram 1200 of a power supply system 15 for a system for moving an object in two or more axes is shown. The power supply system 15 may include a photovoltaic panel 60 mounted on application support 3b connected to a charge controller 61 that controls a battery 62. The charge controller also controls power to a control board 64 to power the computer and communications for the system. The control board 64 also controls power to circuits and other sensors 65, and control valves 63 of the system.

Finally, in many of the embodiments of a system for moving an object in two or more axes, the motive force for the support structure can be provided by any type of fluid pump or compressor with or without a compressed fluid storage. In many embodiments the fluid can be provided by one or more small and efficient rotary vane compressors, requiring less power than a high pressure compressor. Thus, a small solar panel or battery can provide sufficient power to position the entire surface of an application 3a, and also power the control and communications unit while avoiding the large capital expense inherent in coupling external electric power sources to the system.

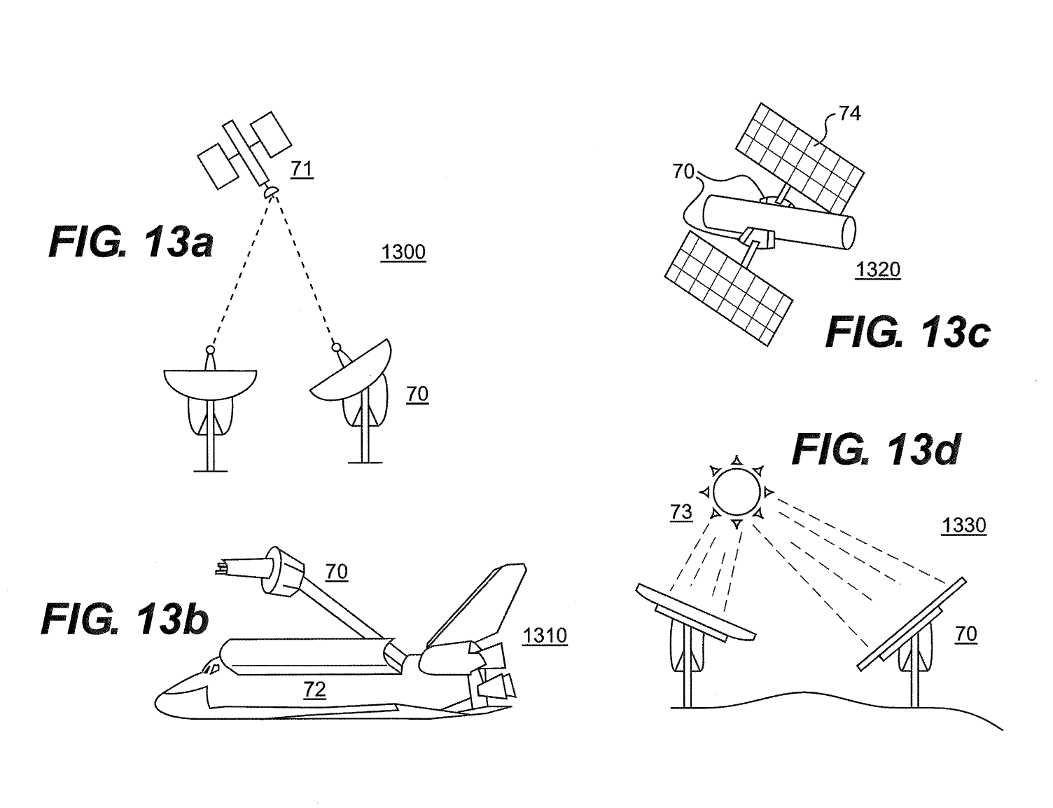

Other exemplary embodiments of the system for moving an object in two or more axes include applications in aerospace, astronomy, and telecommunications, such as the controlled positioning of infrared imaging sensors, electromagnetic radiation antennas or emitters, telescopes, and sensor arrays. For example, FIG. 13a shows a perspective view 1300 of a system for moving an object in two or more axes 70 tracking a telecommunications satellite receiver antenna 71.

FIG. 13b shows a perspective view 1310 of a system for moving an object in two or more axes 70 used on a space vehicle 72 or space station in applications requiring robotic arms or actuators.

Furthermore, FIG. 13c shows a perspective view 1320 of a system for moving an object in two or more axes 70 for rotation of antennae or sensors or solar panels 74 in alignment with radiation sources or receivers.

FIG. 13d shows a perspective view 1330 of a system for moving an object in two or more axes deployed as a heliostat 70 collecting solar power from the sun 73 on a planet in outer space, for example on Mars providing heating for a Mars base station.

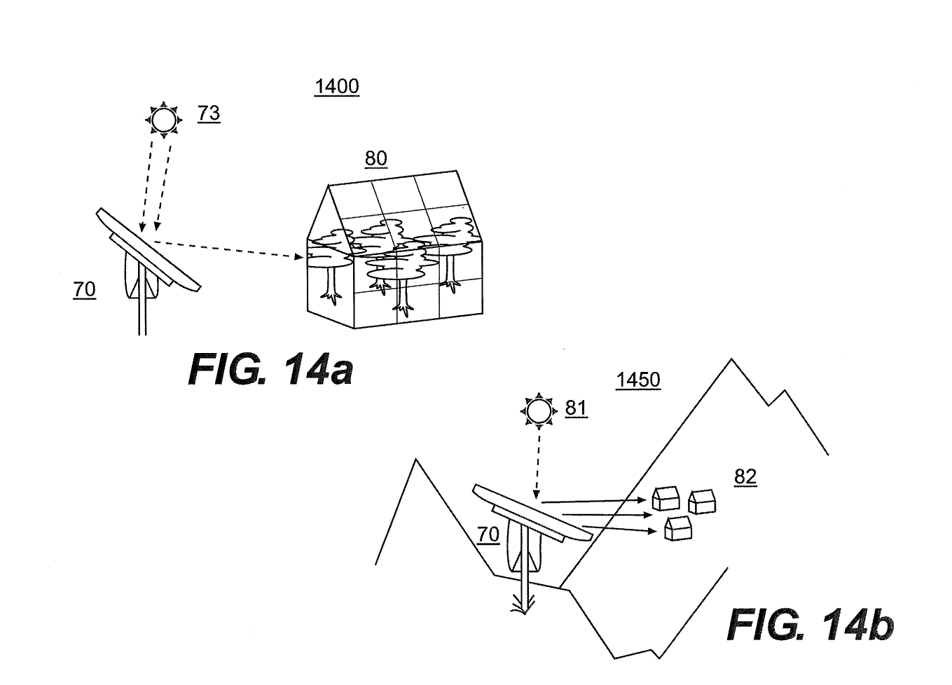

FIGS. 14a and 14b show perspective views 1400 and 1450, of the system for moving an object in two or more axes 70 in relation to the sun 73 embodied as a greenhouse 80 illuminator and as an illumination or heating system for residential or commercial buildings, or for illuminating otherwise shaded public spaces, respectively.

Another embodiment of the system for moving an object in two or more axes is in medical and biomedical fields, in which the actuator may be built in various embodiments at various scales for medical devices, diagnostic machinery and robotics, external or internal prostheses or prosthetic implants, as well as devices for minimally invasive and microsurgical applications such as endovascular, endobronchial and endoscopic surgery where sterile saline, or other suitable liquid or fluid may be utilized to drive the actuators.

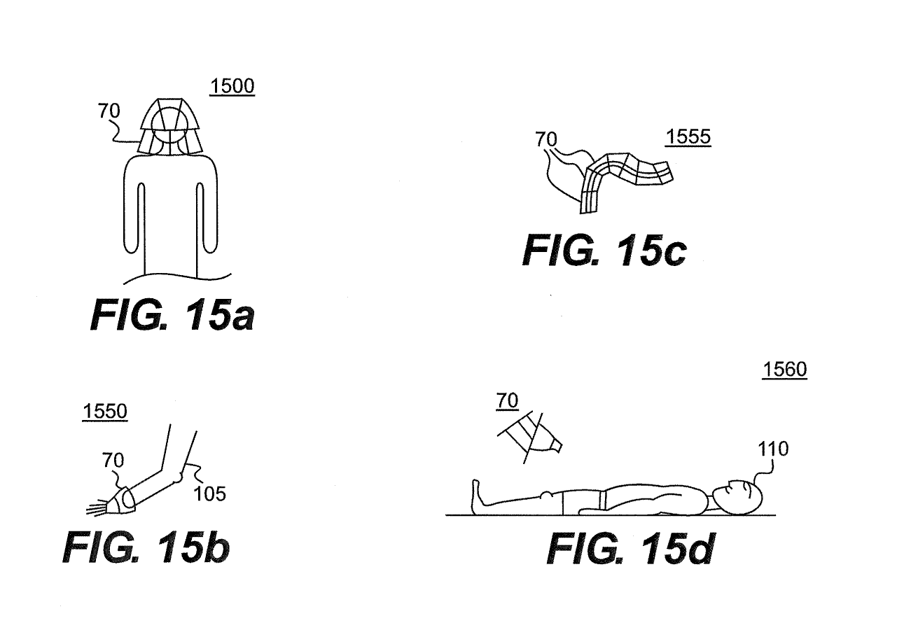

Referring to FIG. 15a, a perspective view 1500 of a system for moving an object in two or more axes embodied as medical robotics actuator 70 is shown.

Referring to FIG. 15b, a perspective view 1550 of a system for moving an object in two or more axes 70 embodied as a prosthesis for a missing limb 105 is shown.

Referring now to FIG. 15c, a perspective view of a system for moving an object in two or more axes 70 is shown embodied as a micro-surgical manipulator 1555 for various types of surgery, such as endovascular surgery or micro-surgery via laparoscope, for example.

Referring now to FIG. 15d, a perspective view 1560 is shown of a system for moving an object in two or more axes employed to position a radiation source 70 used for medical treatment on a person 110.

The system for moving an object in two or more axes can be an embodiment that includes all other various applications such as for general trade, civil engineering, and manufacturing, in which the device is deployed to position advertising materials, construction equipment, or other trade or recreational or consumer goods such as patio umbrellas, sun shades, or any other small or large object, for example. The system may also be used or adapted to remote or robotic purposes, including underwater and trenchless or tunneling technologies, to position tools, materials and machines for handling, inspection, fabrication, repair, and remote operation at any size or scale from macro scale to nanotechnology scale in any number of manufacturing, civil infrastructure and trade contexts not already named above.

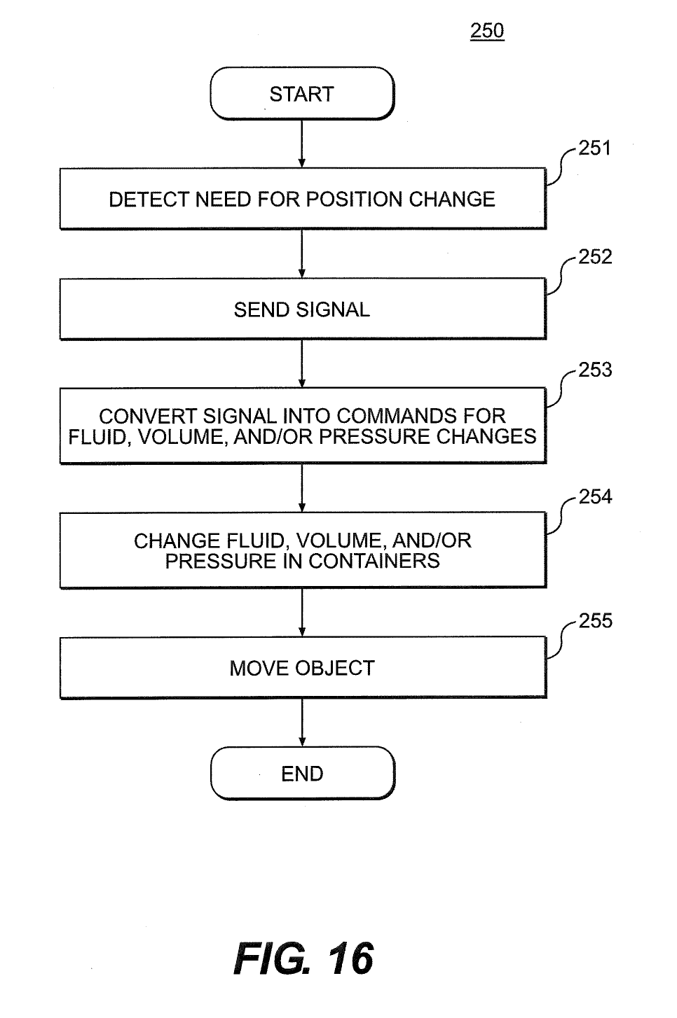

Referring now to FIG. 16, a flow-chart 250 is shown for a method for moving an object in two or more axes. The exemplary method includes providing at least two fluid containers, providing a pivot point 7 (FIG. 1), providing a guidance system that detects a need for a change in position 251 and sends a data signal 252 to a control unit 14, which interprets the data signal and converts the data signal into commands for pressure changes or fluid volume changes 253. The control unit 14 activates one or more pumps via signals to change the volume and pressure 254 of the fluids in one or more of the fluid containers 9.

The change of the volume in one or more of the fluid containers causes a change in pressure 255, which moves the object 3a. The object or application 3a may be moved by applying pressure on the object at one or more locations using pressurized fluid, and changing the pressure applied at a location by changing the volume of the pressurized fluid. An exemplary embodiment of the method for moving an object in two or more axes includes applying pressure on three location of the object 3a. The pivot point may be created by the three locations without a mechanical fulcrum or support.

Embodiments of the exemplary system for moving an object in two or more axes are described with reference to the accompanying drawings, in which some, but not all embodiments of a system for moving an object in two or more axes are shown. The system for moving an object in two or more axes may be embodied in many different forms and should not be construed as limited to the embodiments set forth herein. The drawing/figures are not necessarily to scale or proportion and certain features of the system for moving an object in two or more axes may be shown exaggerated in scale or in somewhat schematic form for clarity.

In the foregoing detailed description, systems and methods in accordance with embodiments of the system for moving an object in two or more axes are described with reference to specific exemplary embodiments. Accordingly, the present specification and figures are to be regarded as illustrative rather than restrictive. The scope of the system for moving an object in two or more axes is to be further understood by the numbered examples appended hereto, and by their equivalents.

Further, in describing various embodiments, the specification may present a method and/or process as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process should not be limited to the performance of their steps in the order written, and one skilled in the art can readily appreciate that the sequences may be varied and still remain within the spirit and scope of the various embodiments.

1. A system for moving an object in two or more axes, comprising:
three or more fluid containers, wherein each of the three or more fluid containers is in contact with the object, and wherein a volume of the fluid is placed in at least one of the three or more fluid containers;
a fluid mover operably connected to the three or more fluid containers for moving the fluid into the three or more fluid containers; and
a fluid volume control for controlling the volume of fluid in the three or more fluid containers, wherein by changing the volume of fluid in the three or more containers the object is moved.

2. The system of claim 1, wherein the contact is indirect contact.

3. The system of claim 1, further comprising a fluid, wherein the fluid is comprised of: air, water, gas, oil, high density fluid, high viscosity fluid, wax, and/or a solid at ambient temperature.

4. The system of claim 1, wherein the object has a top, a bottom, and a side, and wherein all of the three or more fluid containers are located at one of the top, bottom or side of the object.

5. The system of claim 1, wherein the object has a top and a bottom, and wherein some of the three or more fluid containers are on the top of the object while some are at the bottom.

6. The system of claim 1, further comprising a connection between two of the fluid containers for passing fluid.

7. The system of claim 1, wherein the fluid mover is a pump.

8. The system of claim 1 wherein the fluid mover is a high pressure actuator.

9. The system of claim 1, wherein the fluid volume control further comprises sensors.

10. The system of claim 1, wherein the object is one or more of a photovoltaic panel, a solar reflecting mirror, an infrared imaging sensor, an electromagnetic radiation antenna or emitter, a telescope, a satellite, a sensor array, a detector, a medical device, a medical robotics actuator, a diagnostic machinery and robot, an external or internal prostheses or prosthetic implant, a surgical or micro-manipulation tool or device, an advertising material, signage, construction equipment, a patio umbrella, and a sun shade.

11. The system of claim 1, further comprising an elastic tensioning device for stabilizing the object.

12. The system of claim 1, further comprising an elastic tensioning device, wherein one or more of the fluid containers are substituted by an elastic tensioning device.

13. A system for moving an object, comprising:
two or more fluid containers, wherein each of the one or more fluid containers is in contact with the object, and wherein a volume of a fluid is placed in at least one of the said fluid containers;
a pivot point upon which the object moves;
a fluid mover connected to the two or more fluid containers for moving the fluid into the two or more containers; and
an automated fluid volume control for controlling the volume of fluid in the two or more containers, wherein by changing the volume of fluid in the one or more containers the object is moved.

14. The system of claim 13, wherein one of the fluid containers further comprises one or more elastic tensioning devices for stabilizing the object.

15. The system of claim 14, wherein the elastic tensioning devices are spring-loaded tensioning cables.

16. The system of claim 13, further comprising two fluid containers opposing each other, wherein one fluid container is at the top of the object and one fluid container is at the bottom of the object.

17. A system for moving an object in two or more axes, comprising:
a support structure for the object;
an upper support structure fixed to an underside of the support structure;
a central support structure located beneath the support structure;
a connecting linkage between the upper support structure and the central support structure such that the support structure can freely pivot upon the central support;
a lower support structure located circumferentially around the central support structure;
three or more fluid inflatable containers secured circumferentially around the central support structure such that pressurization of the fluid inflatable containers exerts force upon the upper support structure and upon the lower support structure;
one or more control valves connected to the three or more fluid inflatable containers, for pressurizing the three or more fluid inflatable containers, wherein by changing the volume of fluid in the three or more containers the object is moved; and
a source of compressed fluid operatively connected to each of the one or more control valves for pressurizing each of the fluid inflatable containers.

18. The system of claim 17, wherein the system for moving an object in two or more axes is able to orient the support structure in a number of positions by pressurization and depressurization of the fluid inflatable containers such that forces imposed by the fluid inflatable containers against the upper support and lower support are simultaneously opposed by the compressive force imposed by the upper support structure and linkage to the central support structure and the expansive and compressive forces imposed by the other fluid inflatable containers.

19. The system of claim 17 wherein the connecting linkage comprises a universal joint.

20. The system of claim 17 wherein the force exerted by the fluid inflatable containers upon the upper support structure and lower support structure is simultaneous.

21. The system of claim 17 wherein the central support structure is at ground level; and
the lower support structure further comprises the ground.

22. The system of claim 17, wherein the fluid is a solid at ambient temperature and can be heated by a heating device and transformed to a liquid to move the object, wherein after the object is in place, the liquid may be cooled and transformed back to a solid fluid.

23. The system of claim 17, wherein the upper support structure is of a curved, inverted shape.

24. The system of claim 17, wherein the lower support structure is of an inverted, cone shape; and
wherein the lower support structure supports the fluid inflatable containers.

25. The system of claim 17, further comprising:
a compressor;
an electronic pressure sensor connected to each of the fluid inflatable containers;
electronic actuators for the one or more control valves for pressurizing the fluid inflatable containers;
electronic level sensors for determining an altitude, azimuth, and pitch of the object; and
a computer.

26. The system of claim 25, wherein the computer controls the motion of the support structure to maintain the position of the support structure for solar energy collection by electronically actuating the one or more control valves in response to signals received from the electronic pressure sensor and the electronic level sensors.

27. The system claim 25, wherein the computer is capable of communicating output values of the electronic pressure sensor and the electronic level sensors, and positions of the one or more control valves through electromagnetic signals.

28. The system of claim 25, wherein the computer is integrated with the support structure and communicates output values of the electronic pressure sensor and the electronic level sensors, and positions of the one or more control valves through electromagnetic signals; and
the computer receives and executes commands to reposition the solar energy collecting surface through electromagnetic signals.

29. The system of claim 25, further comprising:
a photovoltaic power source that powers the electronic pressure sensor, the electronic level sensors, the compressor, the one or more control valves, and the computer.

30. The system of claim 25, wherein the computer has wireless communication capabilities and regularly transmits a status of the three or more fluid inflatable containers and outputs values of the electronic pressure sensor, the electronic actuators, the electronic level sensors, and the photovoltaic power source to an external control system.

31. A system for moving an object in two or more axes, comprising:
two or more actuators; wherein each actuator comprises a support structure for the object;
an upper support structure fixed to an underside of the support structure;
a central support structure located beneath the support structure;
a connecting linkage between the upper support structure and the central support structure such that the support structure can freely pivot upon the central support;
a lower support structure located circumferentially around the central support structure;
three or more fluid inflatable containers secured circumferentially around the central support structure such that pressurization of the fluid inflatable containers exerts force upon the upper support structure and upon the lower support structure;
one or more control valves connected to the three or more fluid inflatable containers, for pressurizing the three or more fluid inflatable containers, wherein by changing the volume of fluid in the three or more containers the object is moved; and
an attachment, wherein the lower support structure of at least one actuator indirectly or directly attaches to the upper support structure of another actuator.

32. A method for moving an object in two or more axes using pressurized fluid comprising:
providing a pivot point;
applying pressure on the object on at least three locations using pressurized fluid; and
changing the pressure applied at a location by changing the volume of the pressurized fluid, wherein the change in pressure moves the object.

33. The method of claim 32, wherein the pressure is indirectly applied on the object.

34. The method of claim 32, wherein the object comprises a solar energy collector.

35. The method of claim 32, further comprising the step of collecting solar energy.

36. A method for moving an object in two or more axes using pressurized fluid comprising:
providing at least three fluid containers;
providing a pivot point;
providing a guidance system that sends a signal for a change in position;
providing a control system that receives a signal from the guidance system, interprets the signal, and converts the signal into pressure changes or fluid volume changes;
wherein the control system activates one or more pumps to change the volume of the pressurized fluid in one or more of the fluid containers, and wherein the change in volume of the pressurized fluid moves the object.
